(19) United States
(12) Patent Application Publication
(10) Pub. No.: US 2011/0159411 A1
(43) Pub. Date: Jun. 30, 2011

(54) Phase-shift photomask and patterning method

(76) Inventors: Bennett Olson, Livermore, CA (US); Max Lau, San Ramon, CA (US); Cheng-hsin Ma, San Jose, CA (US); Jian Ma, San Jose, CA (US); Andrew T. Jamieson, San Jose, CA (US)

(21) Appl. No.: 12/655,460

(22) Filed: Dec. 30, 2009

(51) Int. Cl. G03F 1/00; G03F 7/20

(52) U.S. Cl. 430/5; 430/322; 430/323; 430/324

(57) ABSTRACT

A phase shift photomask blank has a quartz substrate, a lower chrome layer, a light-absorbing MoSi layer, and an upper chrome layer. This mask can be patterned in various ways to form a patterned photomask with both phase shift and binary areas.

### BACKGROUND

### Background of the Invention

In recent years, an increase in integration density in a semiconductor integrated circuit has resulted in a corresponding ever-increasing demand for an increase in fineness in a photomask used in the preparation of this circuit. Conventional lithography systems have reached their limit in terms of the ability to provide a further increased fineness. A phase shift photomask can increase the resolution of the device pattern transferred from the reticle.

### BRIEF DESCRIPTION OF THE DRAWINGS

FIG. 1 is a cross sectional side view that illustrates a phase shift photomask blank.

FIGS. 2 through 11 are cross sectional side views that illustrate one method by which the photomask blank of FIG. 1 may be patterned to form a phase shift mask.

FIGS. 12 through 17 are cross sectional side views that illustrate another method by which the photomask blank of FIG. 1 may be patterned to form a phase shift mask.

FIGS. 18 through 25 are cross sectional side views that illustrate yet another method by which the photomask blank of FIG. 1 may be patterned to form a phase shift mask.

### DETAILED DESCRIPTION

In various embodiments, a novel phase shift photomask blank and methods to pattern the phase shift photomask blank are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment that falls within the scope of the invention, but do not denote that they are necessarily present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

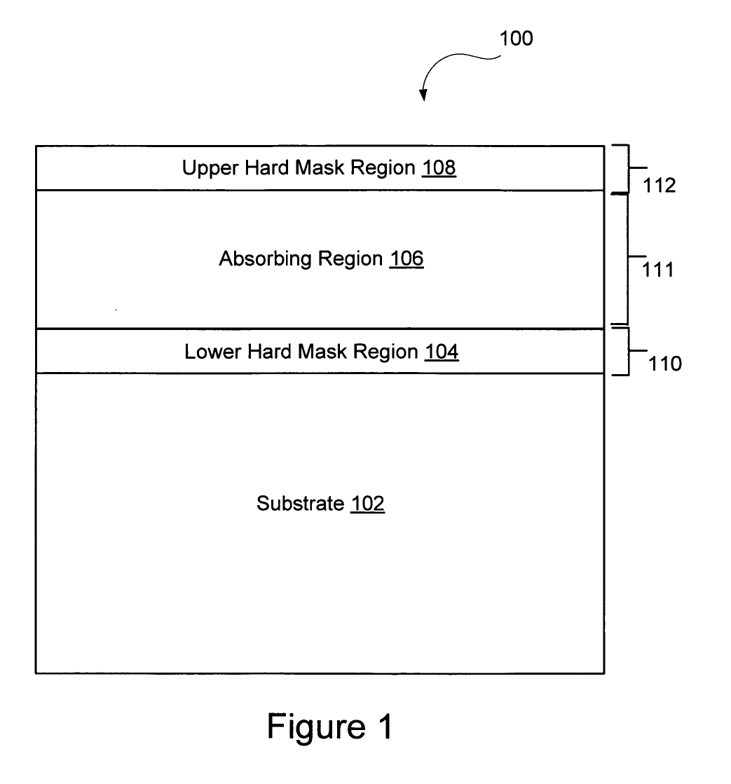

FIG. 1 is a cross sectional side view that illustrates a phase shift photomask blank 100 with multiple thin hard mask regions 104, 108, according to one embodiment of the present invention. Some embodiments of such a photomask blank 100 with multiple thin hard mask regions 104, 108 may allow the photomask blank 100 to have finer resolution than if one thick hard mask region were used, and/or provide good etch selectivity between the substrate 102 and the region 104 immediately adjacent the substrate 102, among other advantages.

The photomask blank 100 includes a substrate 102. The substrate 102 may in various embodiments comprise quartz, silica, fused silica, modified fused silica or any other material suitable for use as a mask.

On the substrate 102 is a lower hard mask region 104. In an embodiment, the lower hard mask region 104 comprises chromium. In various embodiments where the lower hard mask region 104 comprises chromium, the lower hard mask region 104 may be a metal chromium region, or chromium plus another element or elements, such as a chromium oxide region, a chromium nitride region, or a chromium oxynitride region. In some embodiments, the lower hard mask region 104 comprises a chrome subregion capped by a graded or ungraded chrome oxide subregion and/or a graded or ungraded chrome oxynitride subregion. Other suitable materials besides chromium, such as tungsten (in metal form or with other element(s)), tantalum (in metal or with other element(s)), other refractory metals, or other materials may also be used in other embodiments.

In an embodiment, the hard mask region 104 comprises a material with good etch selectivity in a selected etchant compared to the material of the substrate 102. The hard mask region 104 may be in direct contact with the substrate 102 in some embodiments, while in other embodiments there may be other regions or layers between the lower hard mask region 104 and the substrate 102. For example, in an embodiment the substrate 102 comprises quartz, the lower hard mask region 104 comprises chromium, and a chlorine-based etchant is selected, allowing the chromium lower hard mask region 104 to be etched without significantly affecting the quartz substrate 102.

The lower hard mask region 104 has a thickness 110. In some embodiments, the thickness 110 is selected to keep the stress induced on the substrate 102 by the lower hard mask region 104 low, although in some embodiments the selected thickness 110 may not be governed by stress considerations. In an embodiment, the thickness 110 is below 200 angstroms. In an embodiment, the thickness 110 is about 100 angstroms or less. In another embodiment the thickness 110 is below 50 angstroms. In other embodiments different thicknesses 110 may be used.

On the lower hard mask region 104 is an absorbing region 106. In an embodiment, the absorbing region 106 comprises molybdenum and silicon, or MoSi, which may take the form of a molybdenum silicide in some embodiments. In other embodiments, the absorbing region 106 may comprise other materials. In some embodiments, the material of the absorbing region 106 is selected so there is etch selectivity between the absorbing region 106 and one or both of the hard mask regions 104, 108.

When the photomask blank 100 is used, portions of the absorbing region 106 may serve the function of absorbing incident light. In an embodiment, the absorbing region 106 comprises a material with a thickness 111 large enough that the absorbing region 106 has an optical density of 3.0 or more. In an embodiment, the absorbing region 106 comprises a material with a thickness 111 large enough that the absorbing region 106 has an optical density of 2.8 or more. In an embodiment, the absorbing region 106 comprises a material with a thickness 111 large enough that the absorbing region 106 has an optical density of 2.7 or more. In an embodiment, the absorbing region 106 and lower hard mask region 104 comprise materials and have thicknesses 110, 111 that in combination provide an optical density of 3.0 or more. In an embodiment, the absorbing region 106 and lower hard mask region 104 comprise materials and have thicknesses 110, 111 that in combination provide an optical density of 2.8 or more. In an embodiment, the absorbing region 106 and lower hard mask region 104 comprise materials and have thicknesses 110, 111 that in combination provide an optical density of 2.7 or more. Note that the optical densities discussed herein are the optical density in relation to a particular wavelength of light known as the “exposure wavelength.” This exposure wavelength is the wavelength of light that is used with the patterned photomask 100 when using the patterned photomask 100 in a lithography system to pattern a semiconductor wafer. In an embodiment, this exposure wavelength is 193 nanometers. In an embodiment, this exposure wavelength is about 193 nanometers. The exposure wavelength is not limited to about 193 nanometers but encompasses any selected suitable wavelength used with the photomask 100 in a lithography system, and can be 248 nanometers, 157 nanometers, longer wavelengths, or shorter wavelengths (such as in extreme ultraviolet lithography systems). In other embodiments, other In other embodiments the absorbing region 106 and lower hard mask region 104 may have differing optical densities suitable for the photomask blank 100. In an embodiment, the absorbing region 106 has a thickness 111 greater than the combined thicknesses 110, 112 of the hard mask regions 104, 108, although in other embodiments this may not be the case.

In an embodiment, the absorbing region 106 is in direct contact with the lower hard mask region 104 and comprises a material with good etch selectivity in a selected etchant compared to the material of the lower hard mask region 104. For example, in an embodiment the lower hard mask region 104 comprises chromium, the absorbing region 106 comprises MoSi, and a fluorine-based etchant is selected, allowing the absorbing region 106 to be etched without significantly affecting the lower hard mask region 104, which acts as an etch stop. Such etch selectivity is not needed in all embodiments, and in some embodiments the absorbing region 106 may not be in direct contact with the lower hard mask region 104.

On the absorbing region 106 is an upper hard mask region 108. In an embodiment, the upper hard mask region 108 comprises chromium. In various embodiments where the upper hard mask region 108 comprises chromium, the upper hard mask region 108 may be a metal chromium region, or chromium plus another element or elements, such as a chromium oxide region, a chromium nitride region, or a chromium oxynitride region. In some embodiments, the lower upper mask region 108 comprises a chrome subregion capped by a graded or ungraded chrome oxide subregion and/or a graded or ungraded chrome oxynitride subregion. Other suitable materials besides chromium, such as tungsten (in metal form or with other element(s)), tantalum (in metal or with other element(s)), other refractory metals, or other materials may also be used in other embodiments. In some embodiments the upper and lower hard mask regions 104, 108 may consist of substantially the same materials. In some embodiments the upper and lower hard mask regions 104, 108 may comprise the same materials. In some embodiments the upper and lower hard mask regions 104, 108 may comprise different materials.

In an embodiment, the upper hard mask region 108 is in direct contact with the absorbing region 106 and comprises a material with good etch selectivity in a selected etchant compared to the material of the absorbing region 106. For example, in an embodiment the absorbing region 106 comprises MoSi, the upper hard mask region 108 comprises chromium, and a chlorine-based etchant is selected, allowing the chromium upper hard mask region 108 to be etched without significantly affecting the MoSi absorbing region 106. Such etch selectivity is not needed in all embodiments, and in some embodiments the upper hard mask region 108 may not be in direct contact with the absorbing region 106.

The upper hard mask region 108 has a thickness 112. In some embodiments, the thickness 112 is at least twice the thickness 110 of the lower hard mask region 104. In some embodiments, the thickness 112 is at least 1.5 the thickness 110 of the lower hard mask region 104. In some embodiments, the thickness 112 is at least three times the thickness 110 of the lower hard mask region 104. In other embodiments, different relations between the thicknesses 110, 112 of the upper and lower hard mask regions 104, 108 may be used. In an embodiment, the thickness 112 is between 40 nanometers and 20 nanometers. In an embodiment, the thickness 112 is between 10 nanometers and 20 nanometers. In another embodiment the thickness 112 is below 20 nanometers. In other embodiments different thicknesses 112 may be used.

In some embodiments, the thickness 112 and material of the upper hard mask region 108 are selected so that it would take at least 1.5 times as long as long to etch through the upper hard mask region 108 as it would to etch through the lower hard mask region 104 in a selected etchant. In some embodiments, the thickness 112 and material of the upper hard mask region 108 are selected so that it would take at least twice times as long as long to etch through the upper hard mask region 108 as it would to etch through the lower hard mask region 104 in a selected etchant. In some embodiments, the thickness 112 and material of the upper hard mask region 108 are selected so that it would take at least three times as long as long to etch through the upper hard mask region 108 as it would to etch through the lower hard mask region 104 in a selected etchant. In some other embodiments the relative etch times of the upper and lower hard mask regions 108, 104 may be different or may not matter.

In some other embodiments (for example, embodiments where the etch rate of the upper hard mask region 108 in a given etchant is less than the lower hard mask region 104 in the same etchant), the thickness 112 may be equal or less than the thickness 110 of the lower hard mask region 104.

The various regions—the top and bottom hard mask regions 104, 108, the absorbing region 106, and the substrate 102—may each consist of a single material homogenous through the region, or may be a non-homogenous region that includes multiple layers, a graded concentration of various materials, or a combination. For example, the upper hard mask region 108 may consist of homogenous chromium oxynitride, or may be graded with more oxygen present at one position than at another. Also, various additional regions and/or layers may be present in addition to those described here.

The described photomask blank 100 may have various advantages in some embodiments (note that not all embodiments may have all, or even some, of these advantages). The multiple hard mask regions 104, 108 allow separate patterning of the absorbing region 106 and substrate 102 in some embodiments. The multiple hard mask regions 104, 108 allow patterning of the absorbing region 106 and substrate 102 with smaller feature sizes than if one thick hard mask region 108 or a thick chromium region were used and without the use of thick photoresist layers. The absorbing region 106 allows absorption of a selected amount of incident light and can also be used to provide desired binary photomask in some areas of the mask even if other areas of the mask function as a phase shift mask. The chosen materials of the upper hard mask region 108, absorbing region 106, lower hard mask region 104 and substrate 102 may allow for high etch selectivities between each region to provide better feature definition and phase control of the final mask, as well as eased global removal of the absorbing region 106 without affecting the substrate 102. Because two hard mask regions 104, 108 are used they can be relatively thin, which may provide several advantages, including: (1) the use of thinner photoresists to be used to pattern the thin hard mask regions 104, 108, which may allow higher resolution than if thicker photoresists were used; (2) when patterning the hard mask regions 104, 108 the thinner regions allow less biases than if a thicker hard mask region were patterned; and (3) the thinner regions may result in better uniformity when patterning the photomask 100, whereas a thicker hard mask region may result in worse uniformity during patterning. Not every embodiment of the present invention will necessarily include all or even any of these advantages.

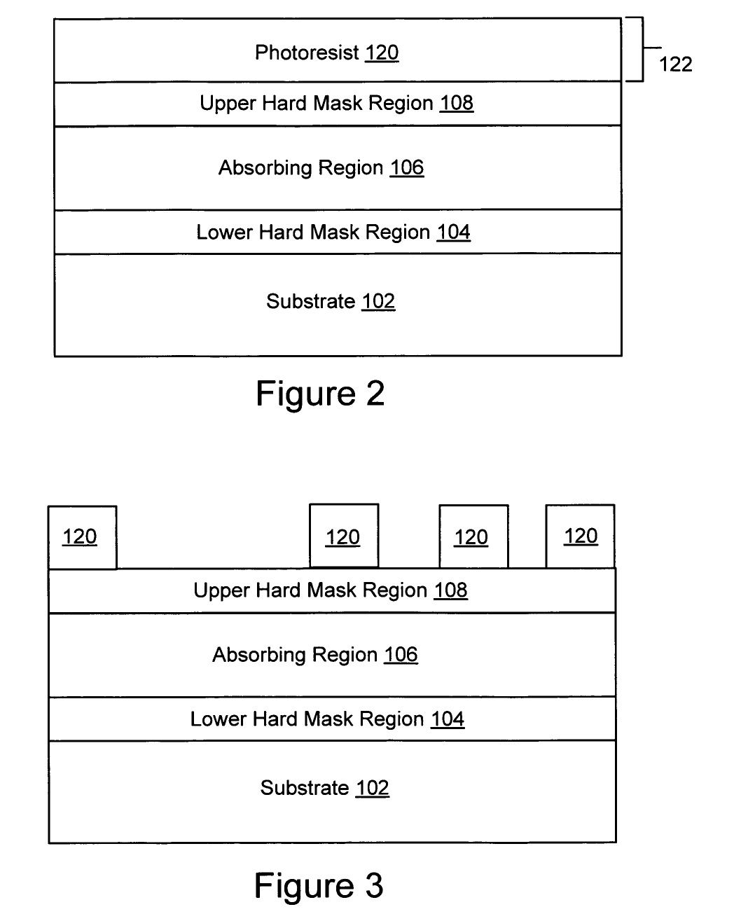

FIGS. 2 through 11 are cross sectional side views that illustrate one method by which the photomask blank 100 of FIG. 1 may be patterned to form a phase shift mask (or reticle).

In FIG. 2 a layer of photoresist 120 has been deposited on the upper hard mask region 108. As the upper hard mask region 108 is not as thick as it would be in a photomask 100 that lacks the absorbing region 106, the photoresist 120 does not have to be as thick as it would be when patterning a photomask 100 with a thicker single region that performs the functions of both the upper hard mask region 108 and the absorbing region 106. In FIG. 3, the photoresist 120 has been patterned to expose portions of the upper hard mask region 108. Any suitable photoresist 120 and patterning method may be used. Also, while the term “photoresist” is used herein, any suitable method or material for patterning may be used, including e-beam patterning, nanoimprintation, and standard photolithography, which may include one or more underlayers or other regions as is understood in the art. The term photoresist as used to describe the process may be substituted by any suitable patternable material and method to pattern such a material. Said material may then be used to transfer the pattern to underlayers by any suitable method. In one embodiment, the layer of photoresist 120 is patterned by e-beam. In some embodiments, the upper hard mask region 108 may comprise a conductive material such as chromium and may thus allow patterning of the photoresist 120 by e-beam without the use of an additional charge dissipation layer.

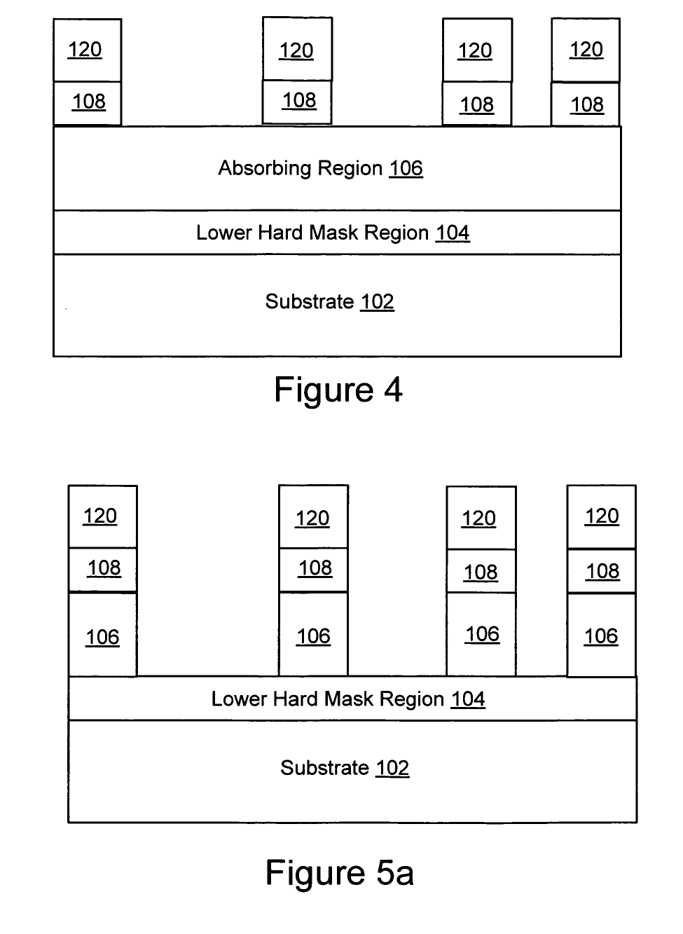

In FIG. 4 the exposed portions of the upper hard mask region 108 have been removed to result in a patterned upper hard mask region 108 and to expose portions of the absorbing region 106. In an embodiment, the removal of the upper hard mask region 108 is achieved by a wet etch with an etchant that selectively removes the material of the upper hard mask region 108 while leaving the absorbing region 106 relatively unaffected. In an embodiment, the upper hard mask region 108 comprises chromium, the absorbing region 106 comprises MoSi, and the etchant is a chlorine-based etchant that removes the exposed portions of the hard mask region 108 while leaving the absorbing region 106 relatively unaffected. In other embodiments, different material removal methods may be used, such as a different wet etch or a dry etch such as a plasma etch.

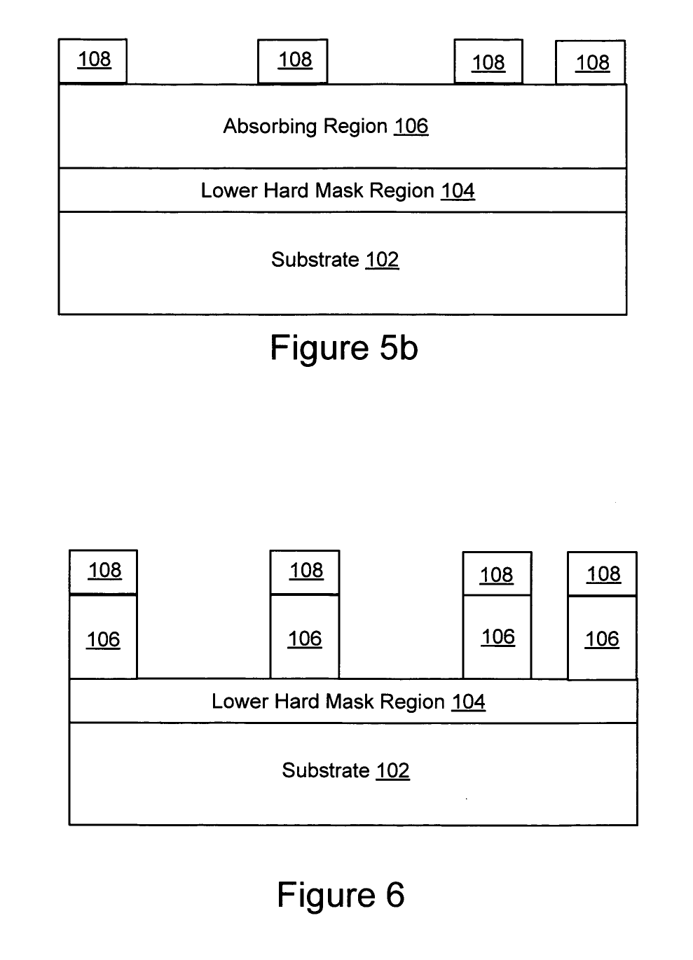

FIGS. 5a and 5b show two alternative approaches that may be used at this point.

In FIG. 5a the exposed portions of the absorbing region 106 have been removed to result in a patterned absorbing region 106 and to expose portions of the lower hard mask region 104. In an embodiment, the removal of the absorbing region 106 is achieved by a wet etch with an etchant that selectively removes the material of the absorbing region 106 while leaving the lower hard mask region 104 relatively unaffected. In an embodiment, the absorbing region 106 comprises MoSi, the lower hard mask region 104 comprises chromium, and the etchant is a fluorine-based etchant that removes the exposed portions of the absorbing region 106 while leaving the lower hard mask region 104 relatively unaffected. In other embodiments, different material removal methods may be used, such as a different wet etch or a dry etch. The remaining portions of the photoresist 120 are then removed.

In an alternative embodiment shown in FIG. 5b, the remaining portions of the photoresist 120 are removed before removing the exposed portions of the absorbing region 106. In such an embodiment, the patterned upper hard mask region 108 serves as a hard mask to pattern the absorbing region 106 without help from the patterned photoresist 120.

FIG. 6 illustrates the device 100 after both the remaining portions of the photoresist 120 and exposed portions of the absorbing region 106 have been removed (in whatever order that occurred), resulting in exposed portions of the lower hard mask region 104.

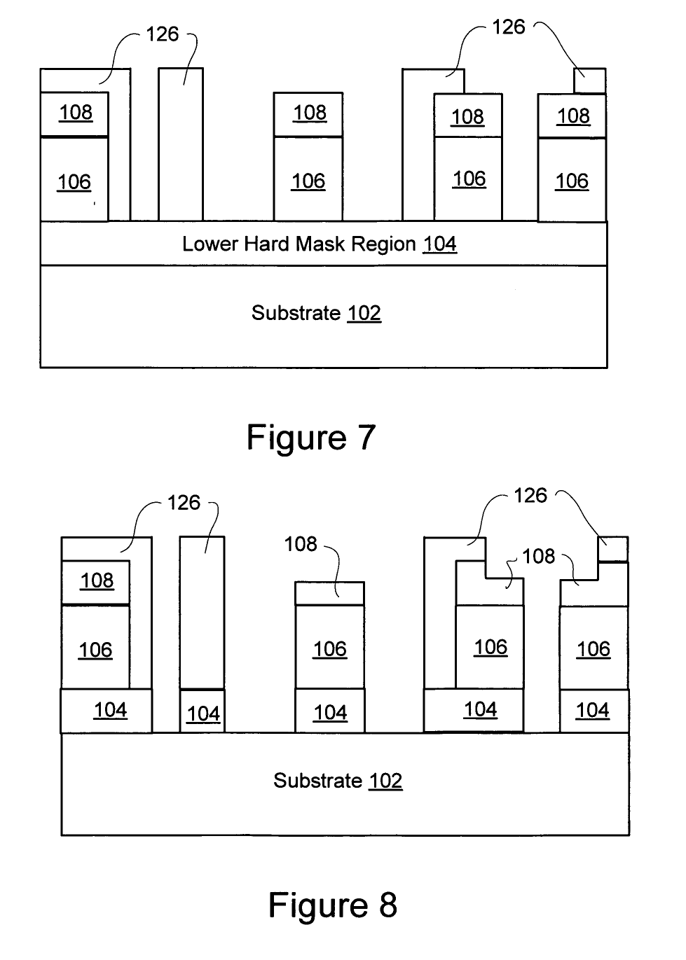

In FIG. 7 a second layer of photoresist 126 has been deposited and patterned. This second layer of photoresist 126 may be patterned in multiple ways in different embodiments. In one embodiment, the second layer of photoresist 126 is patterned by e-beam. In some embodiments, the lower hard mask region 104 may comprise a conductive material such as chromium and may thus allow patterning of the photoresist 126 by e-beam without the use of an additional charge dissipation layer that may be required when photomask blanks 100 that lack the lower hard mask region 104 are used. This patterned second photoresist 126 covers some of the lower hard mask region 104 and leaves some of the lower hard mask region 104 exposed and further covers some of the remaining upper hard mask region 108. In this example of a process flow, the second layer of patterned photoresist 126 does not have edges that need to line up with the already-present sidewalls of the absorbing region 106 and upper hard mask region 108.

In FIG. 8 the exposed portions of the lower hard mask region 104 not covered by the second photoresist 126 have been removed to result in a patterned lower hard mask region 104 and to expose portions of the substrate 102. In an embodiment, the removal of the lower hard mask region 104 is achieved by a wet etch with an etchant that selectively removes the material of the lower hard mask region 104 while leaving substrate 102 and absorbing region 106 relatively unaffected. In an embodiment, the lower hard mask region 104 comprises chromium, the substrate 102 comprises quartz, and the etchant is a chlorine-based etchant that removes the exposed portions of the lower hard mask region 104 while leaving the substrate 102 and absorbing region 106 relatively unaffected. In other embodiments, different material removal methods may be used, such as a different wet etch or a dry etch such as a plasma etch.

As illustrated, the same etchant or other removal method that removes the exposed portions of the lower hard mask region 104 also removes at least some of the upper hard mask region 108 not covered by the second photoresist 126. As mentioned previously, in some embodiments both the upper and lower hard mask regions 104, 108 may not be susceptible to the same etchant or other removal process. Thus, in some embodiments, the portions of the upper hard mask region 108 illustrated as having been removed may remain in place.

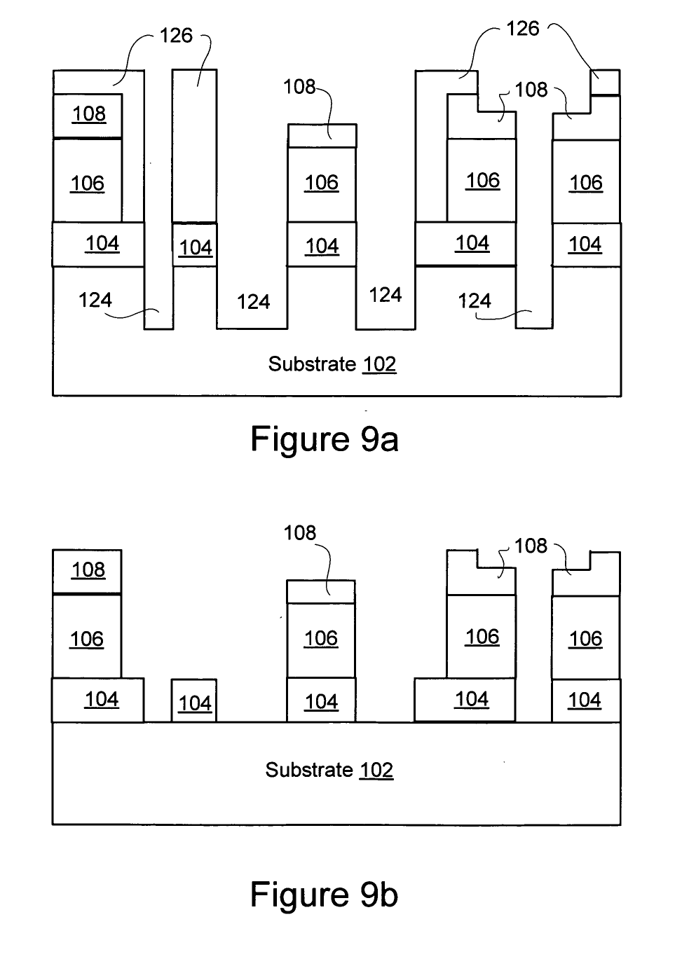

FIGS. 9a and 9b show two alternative approaches that may be used at this point.

In FIG. 9a at least some of the exposed portions of the substrate 102 have been removed to make trenches 124 in the substrate 102, while the second photoresist 126 remains in place. These trenches 124 serve to phase shift incident light to make the final mask a phase shift mask. In an embodiment, the removal of the substrate 102 is achieved by a wet etch appropriate for the substrate 102 material. In an embodiment, the substrate 102 comprises quartz and the etchant is a fluorine-based etchant that removes the exposed portions of the substrate 102. In other embodiments, different material removal methods may be used, such as a different wet etch or a dry etch. After the trenches are formed, the remaining portions of the second photoresist 126 are removed.

In an alternative embodiment shown in FIG. 9b, the remaining portions of the second photoresist 126 are removed before forming trenches 124 in the substrate 102. In such an embodiment, the patterned upper and/or lower hard mask regions 108, 104 serve as a hard mask to pattern the substrate 102 without help from the patterned second photoresist 126.

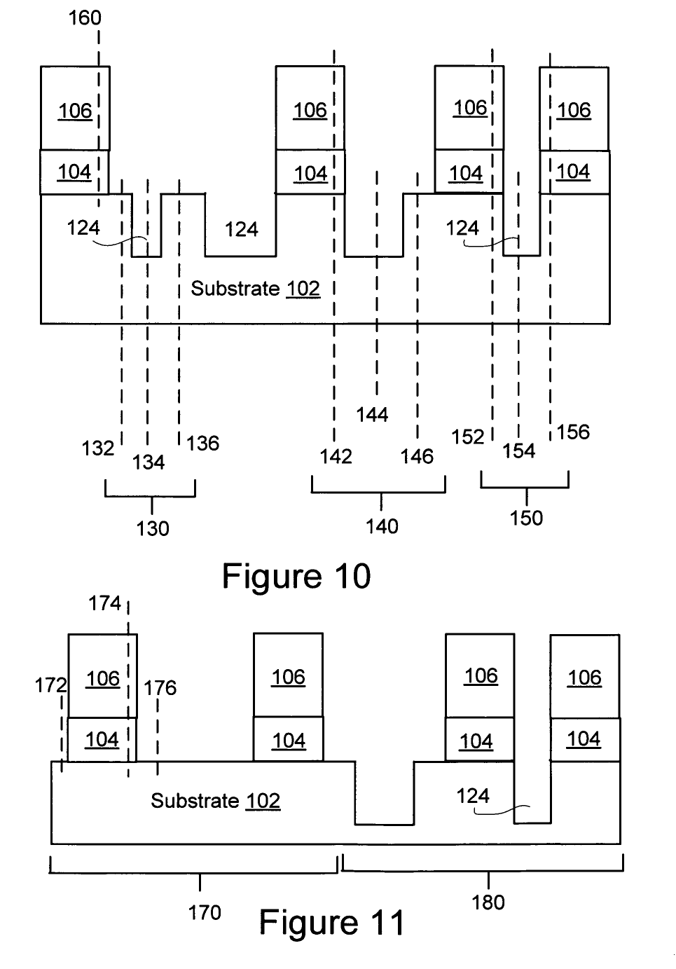

FIG. 10 illustrates the device 100 after both the remaining portions of the second photoresist 126 are removed and trenches 124 are formed in the substrate 102 (in whatever order that occurred), and the remaining portions of the upper hard mask region 108 and remaining exposed portions of the lower hard mask region 104 are removed, resulting in a photomask with features 130, 140, 150. (Note that removal of the remaining exposed portions of the lower hard mask region 104 may tend to remove the remaining portions of the upper hard mask region 108 in some embodiments. In other embodiments, portions of the upper hard mask region 108 may remain in place on the absorbing region 106. These remaining upper hard mask portions 108 may or may not then be removed.) Each of features 130, 140, 150 has different transitions from left to right along the feature. All three types of features, or a subset of the feature types may be present on the patterned phase shift mask in various embodiments.

Note that while the phase values of 0 (zero) and pi are used as examples of phase shift features herein, they are only consistently used to avoid confusion, not to imply that they are the only phase shift values that may be used. Methods described herein may be used to pattern the photomask blank 100 into a mask with any suitable phase shift values. For example, phase shift values of 5 degrees and 185 degrees may be created by a short final substrate 102 etch. Other phase shift values may also be used.

Feature 130 has a phase shift of 0 (zero) at location 132, a phase shift of pi at location 134, and a phase shift of zero again at location 136. Such transitions between a phase shift of zero and pi may be used as all the features of a phase shift mask. In other embodiments, other types of transitions in addition and/or in place of the zero/pi transition may be used. Note that the patterning of the second photoresist 126 defined the position of the transition between zero-phase shift location 132 and light blocking location 160, while the patterning of the second photoresist 126 defined the width of the pi-phase shift trench 124 of feature 130.

Feature 140 has an absorber at location 142 that blocks incident light, has a phase shift of pi at location 144, and a phase shift of zero at location 146. Thus, this feature 140 is a hybrid between light-blocking and phase shifting locations. Note that the first photoresist 120 defined the position of the transition between light blocking location 142 and pi-phase shift location 144, while the second photoresist 126 defined the position between pi-phase shift location 144 and zero-phase shift location 146.

Feature 150 has an absorber at location 152 that blocks incident light, has a phase shift of pi at location 154, and has an absorber at location 156 that blocks incident light. Thus, this feature 150 does not just phase-shift light, but has a phase shift flanked by light blocking.

FIG. 11 is similar to FIG. 10, and illustrates that the patterned photomask may have one or more binary areas 170 in addition to the phase-shift areas 180 described above. The phase shift areas 180 may have one or more feature types 130, 140, 150 that phase-shift incident light. In an embodiment, the binary areas 170 lacks trenches 124 in the substrate 102, and does not phase-shift light. Instead, light in the binary area 170 is either blocked or not blocked. For example, locations 172, 174, 176 may be part of a feature. Location 172 lacks an absorbing region 106, so it does not block light. Location 174 has a portion of the absorbing region 106, so blocks light. Location 176 lacks an absorbing region 106, so it does not block light. This binary area 170 may be, for example, at the periphery of the photomask, and used to pattern features such as alignment marks on a semiconductor wafer, although the binary area 170 may be in other locations and used for other purposes in other embodiments. In some embodiments, the mask may lack this binary area 170, having only the phase shift area 180.

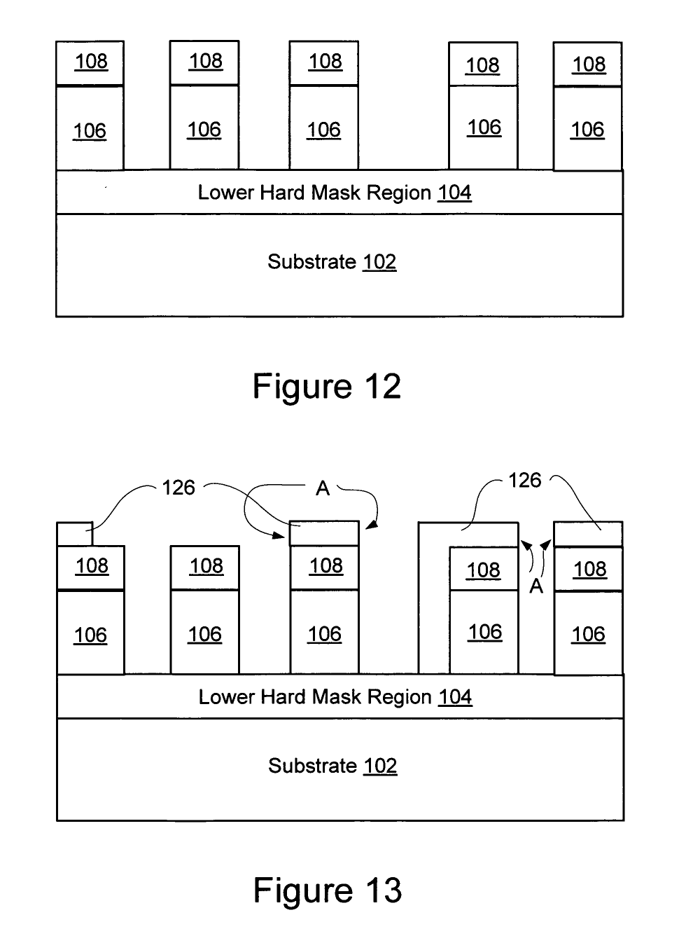

FIGS. 12 through 17 are cross sectional side views that illustrate another method by which the photomask blank 100 of FIG. 1 may be patterned to form a phase shift mask (or reticle). In an embodiment, the method may begin in the same manner as described above with respect to FIGS. 2 through 5.

FIG. 12 illustrates the device 100 after both the remaining portions of the photoresist 120 and exposed portions of the absorbing region 106 have been removed (in whatever order that occurred), resulting in exposed portions of the lower hard mask region 104.

In FIG. 13 a second layer of photoresist 126 has been deposited and patterned. This second layer of photoresist 126 may be patterned in multiple ways in different embodiments. In one embodiment, the second layer of photoresist 126 is patterned by e-beam. In some embodiments, the lower hard mask region 104 may comprise a conductive material such as chromium and may thus allow patterning of the photoresist 126 by e-beam without the use of an additional charge dissipation layer that may be required when photomask blanks 100 that lack the lower hard mask region 104 are used. This second photoresist 126 covers some of the lower hard mask region 104 and leaves some of the lower hard mask region 104 exposed, and further covers some of the remaining upper hard mask region 108. As illustrated in the embodiment shown FIG. 13, the second layer of patterned photoresist 126 has edges “A” that are aligned with previously present edges of the patterned upper hard mask 108 and absorbing 106 regions, although such alignment is not present at other edges of the patterned photoresist 126, and such alignment may not exist at all in some embodiments.

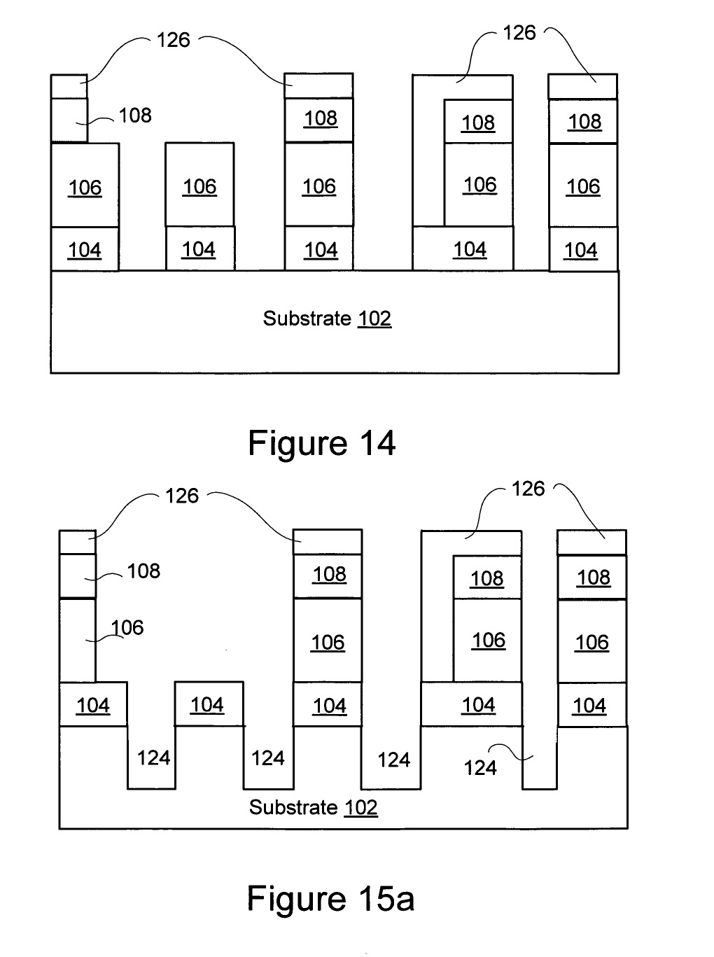

In FIG. 14 the exposed portions of the lower hard mask region 104 not covered by the second photoresist 126 have been removed to result in a patterned lower hard mask region 104 and to expose portions of the substrate 102. In an embodiment, the removal of the lower hard mask region 104 is achieved by a wet etch with an etchant that selectively removes the material of the lower hard mask region 104 while leaving the absorbing region 106 and substrate 102 relatively unaffected. In an embodiment, the lower hard mask region 104 comprises chromium, the substrate 102 comprises quartz, and the etchant is a chlorine-based etchant that removes the exposed portions of the lower hard mask region 104 while leaving the substrate 102 and absorbing region 106 relatively unaffected. In other embodiments, different material removal methods may be used, such as a different wet etch or a dry etch such as a plasma etch.

As illustrated, the same etchant or other removal method that removes the exposed portions of the lower hard mask region 104 also removes at least some of the upper hard mask region 108 not covered by the second photoresist 126. As mentioned previously, in some embodiments both the upper and lower hard mask regions 104, 108 may not be susceptible to the same etchant or other removal process. Thus, in some embodiments, the portions of the upper hard mask region 108 illustrated as having been removed may remain in place.

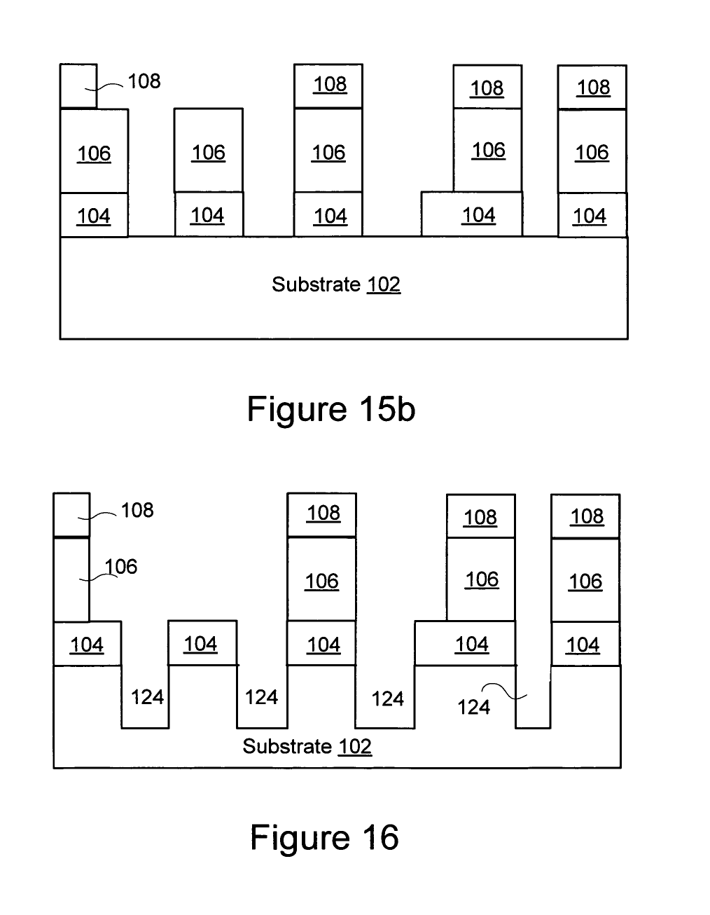

In FIG. 15a at least some of the exposed portions of the substrate 102 have been removed to make trenches 124 in the substrate 102, while the second photoresist 126 remains in place. These trenches 124 serve to phase shift incident light to make the final mask a phase shift mask. In an embodiment, the removal of the substrate 102 is achieved by a wet etch appropriate for the substrate 102 material. In an embodiment, the substrate 102 comprises quartz and the etchant is a fluorine-based etchant that removes the exposed portions of the substrate 102. In other embodiments, different material removal methods may be used, such as a different wet etch or a dry etch such as a plasma etch. In the illustrated embodiment, the absorbing region 106 is removed by the same removal method used to form the trenches 124 in the substrate, so exposed portions of the absorbing region 106 are removed as well. In other embodiments, the absorbing region 106 may not be susceptible to the same etchant (for example) as the substrate 102 and the exposed portions of the absorbing region 106 may be removed in a separate step before or after the trenches 124 are formed. After the trenches 124 are formed, the remaining portions of the second photoresist 126 are removed.

In an alternative embodiment shown in FIG. 15b, the remaining portions of the second photoresist 126 are removed before forming trenches 124 in the substrate 102. In such an embodiment, the patterned upper and/or lower hard mask regions 108, 104 serve as a hard mask to pattern the substrate 102 without help from the patterned second photoresist 126. As mentioned above with respect to FIG. 15a, the exposed portions of the absorbing region 106 may be removed at the same time the trenches 124 are formed in the substrate 102.

FIG. 16 illustrates the device 100 after both the remaining portions of the second photoresist 126 are removed and trenches 124 are formed in the substrate 102 (in whatever order that occurred).

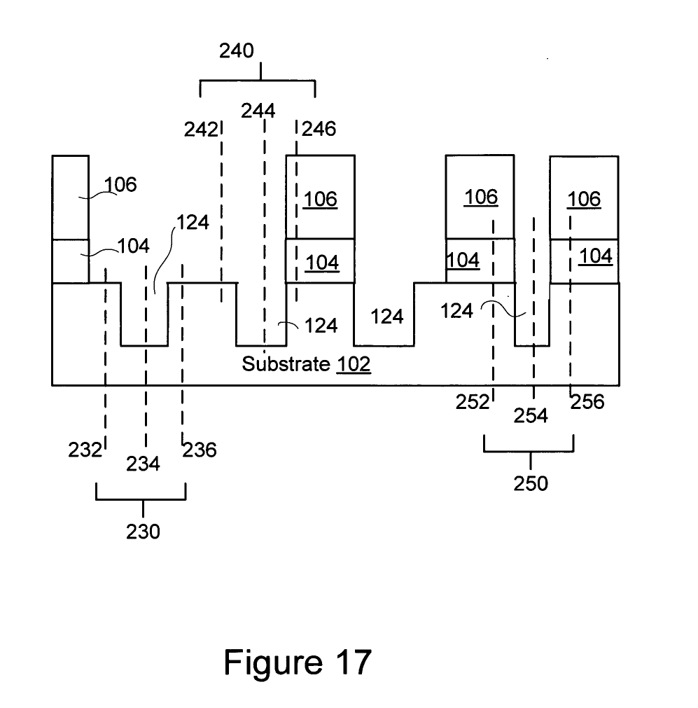

FIG. 17 illustrates the device 100 after the remaining portions of the upper hard mask region 108 and remaining exposed portions of the lower hard mask region 104 are removed, resulting in a photomask with features 230, 240, 250. (Note that removal of the remaining exposed portions of the lower hard mask region 104 may tend to remove the remaining portions of the upper hard mask region 108 in some embodiments, such as that illustrated in FIG. 17. In other embodiments, portions of the upper hard mask region 108 may remain in place on the absorbing region 106 after removal of the remaining exposed portions of the lower hard mask regions 104. These remaining upper hard mask portions 108 may or may not then be removed.) Each of features 230, 240, 250 has different transitions from left to right along the feature. All three types of features, or a subset of the feature types may be present on the patterned phase shift mask in various embodiments.

Feature 230 has a phase shift of 0 (zero) at location 232, a phase shift of pi at location 234, and a phase shift of zero again at location 236. Such transitions between a phase shift of zero and pi may be used as all the features of a phase shift mask. In other embodiments, other types of transitions in addition and/or in place of the zero/pi transition may be used. Note that the patterning of the first photoresist 120 defined the position of the transitions between zero-phase shift locations 232, 236 and the pi-phase shift location 234.

Feature 240 has a phase shift of zero at location 242, a phase shift of pi at location 244, and an absorber at location 246 that blocks incident light. Thus, this feature 240 is a hybrid between light-blocking and phase shifting locations.

Feature 250 has an absorber at location 252 that blocks incident light, has a phase shift of pi at location 254, and has an absorber at location 256 that blocks incident light. Thus, this feature 250 does not just phase-shift light, but has a phase shift flanked by light blocking.

There may be areas of the mask that are binary masks rather than phase shift masks, similar to the areas 170, 180 illustrated in FIG. 11.

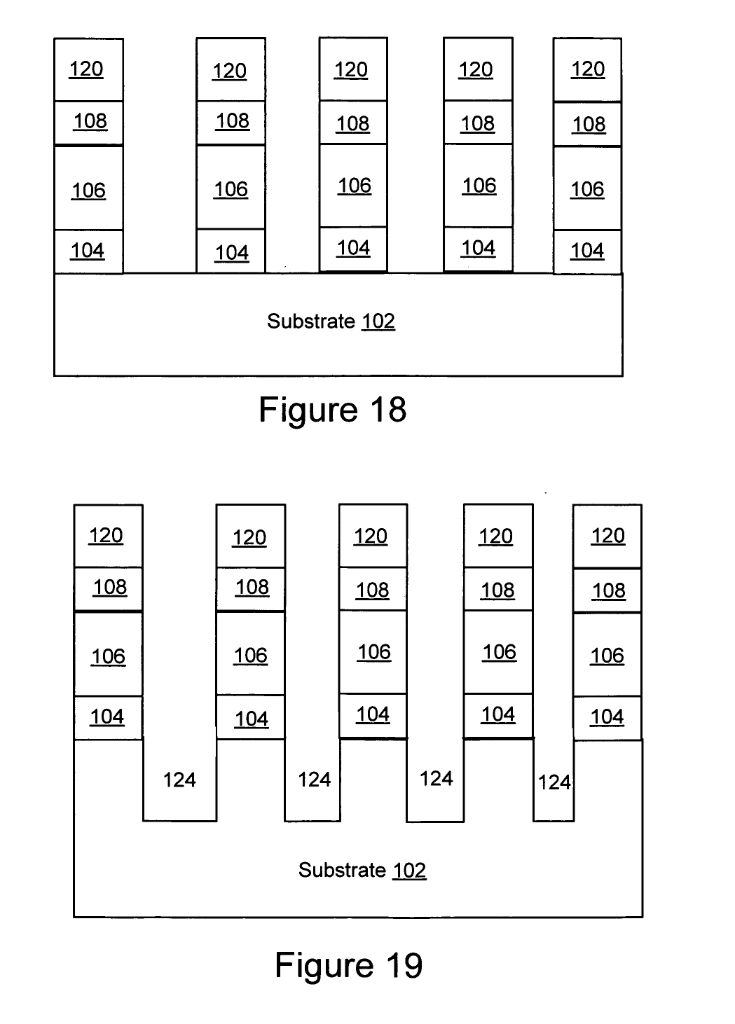

FIGS. 18 through 25 are cross sectional side views that illustrate yet another method by which the photomask blank 100 of FIG. 1 may be patterned to form a phase shift mask (or reticle). In an embodiment, the method may begin in the same manner as described above with respect to FIGS. 2 through 5a.

FIG. 18 illustrates the device 100 after the exposed portions of the lower hard mask region 104 have been removed, resulting in exposed portions of the substrate 102. In an embodiment, the removal of the lower hard mask region 104 is achieved by a wet etch with an etchant that selectively removes the material of the lower hard mask region 104 while leaving the absorbing region 106 and substrate 102 relatively unaffected. In an embodiment, the lower hard mask region 104 comprises chromium, the substrate 102 comprises quartz, and the etchant is a chlorine-based etchant that removes the exposed portions of the lower hard mask region 104 while leaving the substrate 102 and absorbing region 106 relatively unaffected. In other embodiments, different material removal methods may be used, such as a different wet etch or a dry etch such as a plasma etch.

FIG. 19 illustrates the device after at least some of the exposed portions of the substrate 102 have been removed to make trenches 124 in the substrate 102. These trenches 124 serve to phase shift incident light to make the final mask a phase shift mask. In an embodiment, the removal of the substrate 102 is achieved by a wet etch appropriate for the substrate 102 material. In an embodiment, the substrate 102 comprises quartz and the etchant is a fluorine-based etchant that removes the exposed portions of the substrate 102. In other embodiments, different material removal methods may be used, such as a different wet etch or a dry etch.

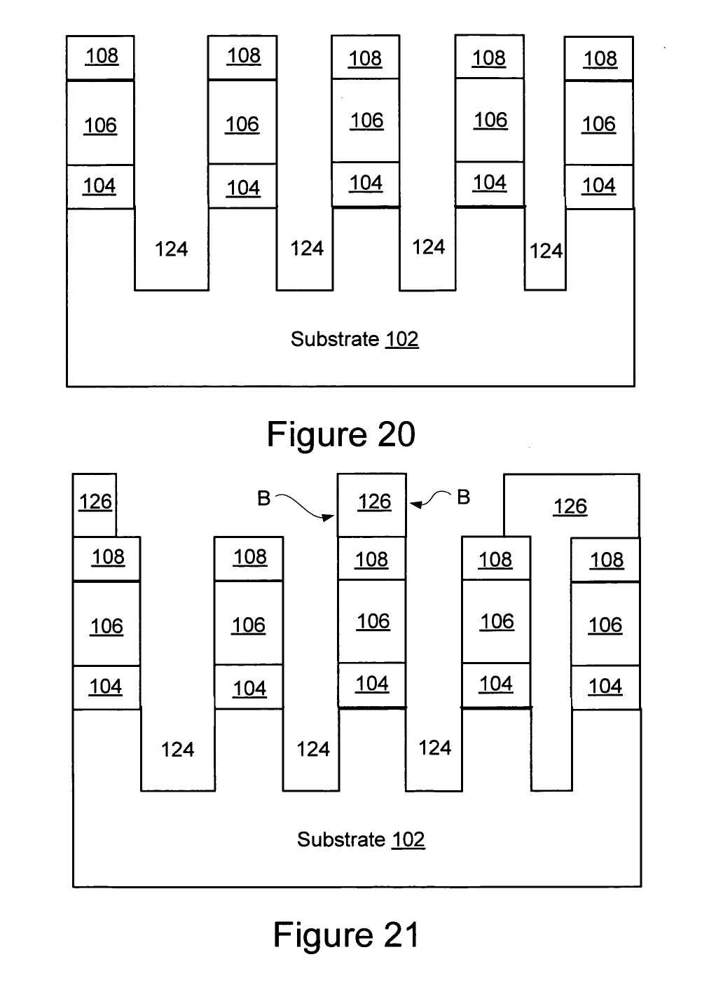

FIG. 20 illustrates the device after the photoresist 120 has been removed. Any suitable method may be used to remove the remaining portions of the photoresist 120.

In FIG. 21 a second layer of photoresist 126 has been deposited and patterned. In one embodiment, the layer of photoresist 120 is patterned by e-beam. In some embodiments, the upper hard mask region 108 may comprise a conductive material such as chromium and may thus allow patterning of the photoresist 120 by e-beam without the use of an additional charge dissipation layer. In other embodiments, different patterning processes may be used. This second photoresist 126 covers some of the upper hard mask region 108 and leaves some of the upper hard mask region 108 exposed, and further covers some of the substrate 124. As illustrated in the embodiment shown in FIG. 21, the second layer of patterned photoresist 126 has edges “B” that are aligned with previously present edges of the patterned upper hard mask 108 and absorbing 106 regions, while other edges of the photoresist 126 are not so aligned. In FIG. 21, these aligned edges B are present in the middle portion of the patterned second photoresist 126, and are absent from the left and right portions of the patterned second photoresist 126. Some embodiments may completely lack such aligned edges B.

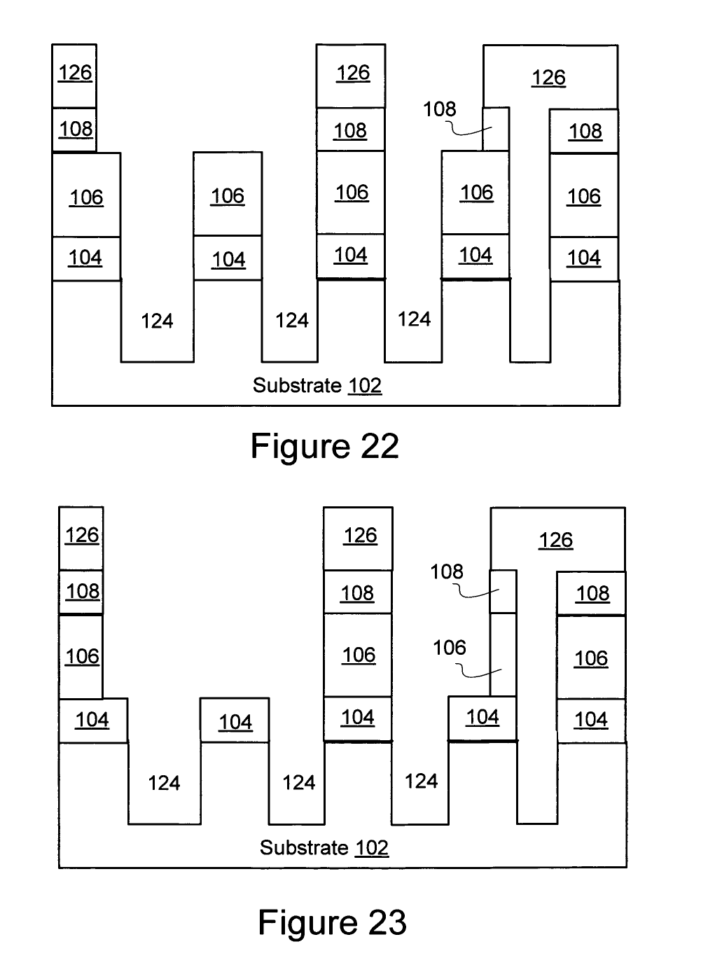

In FIG. 22 the exposed portions of the upper hard mask region 108 not covered by the second photoresist 126 have been removed to result in additional patterning of the upper hard mask region 108 and to expose additional portions of the absorbing region 106. In an embodiment, the removal of the upper hard mask region 108 is achieved by a wet etch with an etchant that selectively removes the material of the upper hard mask region 108 while leaving absorbing region 106 relatively unaffected. In an embodiment, the upper hard mask region 108 comprises chromium, the absorbing region 106 comprises MoSi, and the etchant is a chlorine-based etchant that removes the exposed portions of the hard mask region 108 while leaving the absorbing region 106 relatively unaffected. In other embodiments, different material removal methods may be used, such as a different wet etch or a dry etch.

In FIG. 23 the additional exposed portions of the absorbing region 106 have been removed to result in a patterned absorbing region 106 and to expose additional portions of the lower hard mask region 104. In an embodiment, the removal of the absorbing region 106 is achieved by a wet etch with an etchant that selectively removes the material of the absorbing region 106 while leaving the lower hard mask region 104 relatively unaffected. In an embodiment, the absorbing region 106 comprises MoSi, the lower hard mask region 104 comprises chromium, and the etchant is a fluorine-based etchant that removes the exposed portions of the absorbing region 106 while leaving the lower hard mask region 104 relatively unaffected. In other embodiments, different material removal methods may be used, such as a different wet etch or a dry etch.

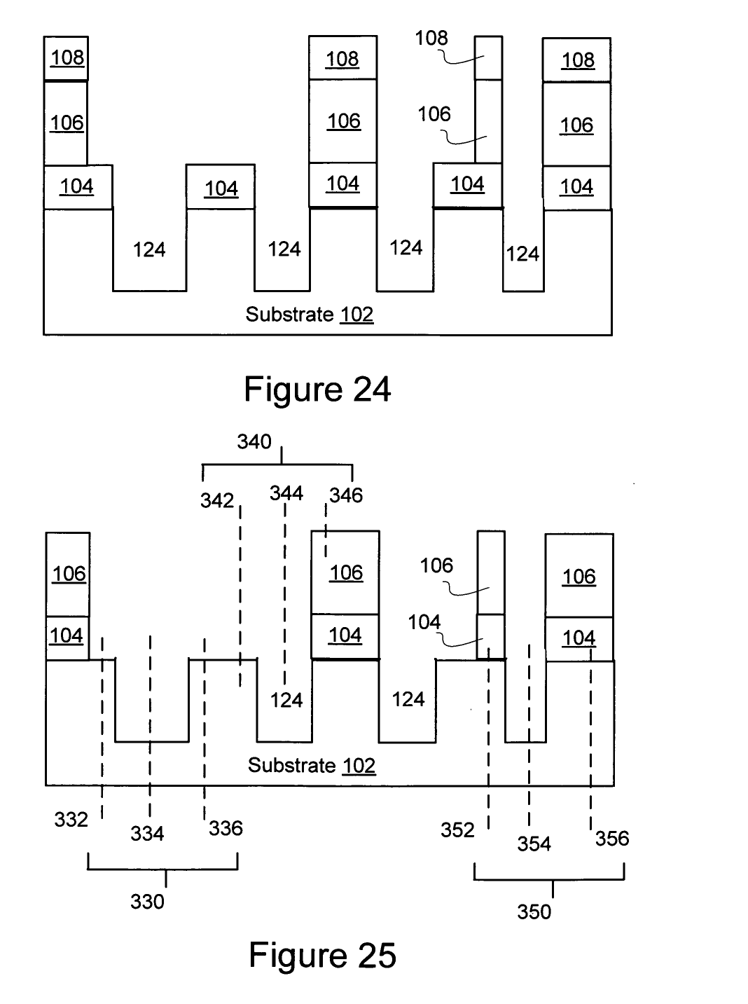

In FIG. 24, the remaining second photoresist 126 portions have been removed, leaving additional exposed portions of the upper hard mask region 108 and trenches 124. Any suitable method may be used to remove the remaining second photoresist 126 portions.

FIG. 25 illustrates the device 100 after the remaining portions of the upper hard mask region 108 and remaining exposed portions of the lower hard mask region 104 are removed, resulting in a photomask with features 330, 340, 350. (Note that removal of the remaining exposed portions of the lower hard mask region 104 may tend to remove the remaining portions of the upper hard mask region 108 in some embodiments, such as that illustrated in FIG. 25. In other embodiments, portions of the upper hard mask region 108 may remain in place on the absorbing region 106 after removal of the remaining exposed portions of the lower hard mask regions 104. These remaining upper hard mask portions 108 may or may not then be removed.) Each of features 330, 340, 350 has different transitions from left to right along the feature. All three types of features, or a subset of the feature types may be present on the patterned phase shift mask in various embodiments.

Feature 330 has a phase shift of 0 (zero) at location 332, a phase shift of pi at location 334, and a phase shift of zero again at location 336. Such transitions between a phase shift of zero and pi may be used as all the features of a phase shift mask. In other embodiments, other types of transitions in addition and/or in place of the zero/pi transition may be used. Note that the patterning of the first photoresist 120 defined the position of the transitions between zero-phase shift locations 332, 336 and the pi-phase shift location 334.

Feature 340 has a phase shift of zero at location 342, a phase shift of pi at location 344, and an absorber at location 346 that blocks incident light. Thus, this feature 340 is a hybrid between light-blocking and phase shifting locations.

Feature 350 has an absorber at location 352 that blocks incident light, has a phase shift of pi at location 354, and has an absorber at location 356 that blocks incident light. Thus, this feature 350 does not just phase-shift light, but has a phase shift flanked by light blocking.

There may be areas of the mask that are binary masks rather than phase shift masks, similar to the areas 170, 180 illustrated in FIG. 11.

Three processes by which the mask blank of FIG. 1 may be patterned to form various types of features have been described. Other methods and variations may also be used to pattern the mask blank in other embodiments. For example, while the mask blank 100 has been described as being patterned to have features with phase shifts in the substrate 102 and the presence or absence of the absorbing region 106, other features may also be patterned. One such feature has a location with a trench in the absorbing region 106 adjacent to a location without a trench in the absorbing region 106. This feature may use the trench/no trench in the absorbing region 106 to create phase shifts similar to how the trenches 124 in the substrate function. In such a feature, the absorbing region 106 combined with the lower hard mask region 104 may have a light transmittance at the exposure wavelength of about 6%, although different light transmittance values may be used.

A photomask, comprising: a phase shift area with a substrate and trenches in the substrate; and a binary area with the substrate, a first hard mask region on the substrate, an absorbing region on the first hard mask region, and wherein the binary region lacks trenches in the substrate. The photomask may also have a second hard mask region on the absorbing region in the binary area. The first and second hard mask regions may comprise chromium. The absorbing region may comprise molybdenum and silicon. The substrate may comprise quartz. The second hard mask region may be at least twice as thick as the first hard mask region.

A method of patterning a photomask blank comprises depositing a first layer of photoresist on a photomask blank, the photomask blank comprising a substrate, a first hard mask region on the substrate, an absorbing region on the first hard mask region, and a second hard mask region on the absorbing region; patterning the first layer of photoresist to expose portions of the second hard mask region; removing exposed portions of the second hard mask region with a first etchant that selectively removes the second hard mask region at a rate greater than the absorbing region, to expose portions of the absorbing region under the removed portions of the second hard mask region; removing exposed portions of the absorbing region with a second etchant that selectively removes the absorbing region at a rate greater than the first hard mask region, to expose portions of the first hard mask region under the removed portions of the absorbing region; depositing a second layer of photoresist on the exposed portions of the first hard mask region; patterning the second layer of photoresist to expose portions of the first hard mask region, other portions of the first hard mask region remaining unexposed under the absorbing region; removing, after patterning the second layer of photoresist, exposed portions of the first hard mask region with a third etchant that selectively removes the first hard mask region at a rate greater than the substrate, to expose portions of the substrate under the removed portions of the first hard mask region; and removing exposed portions of the substrate to form trenches in the substrate. Both the first hard mask region and the second hard mask region may comprise chromium and the second hard mask region may have a thickness of at least twice that of the first hard mask region. The absorbing region may comprise MoSi and have a thickness great enough that the absorbing region has an optical density of at least 2.0. The substrate may comprise quartz that is in direct contact with the chromium of the first hard mask region. The second hard mask region may have a thickness of 40 nanometers or less and the first hard mask region may have a thickness of 20 nanometers or less. The absorbing region may comprise MoSi and have a thickness greater than the combined thickness of the first and second hard mask regions. Patterning the second layer of photoresist may comprise using an e-beam to pattern the second layer of photoresist, and the second hard mask region may comprise chromium and function as a charge dissipation layer during the e-beam patterning. At least some of the trenches may have a sidewall aligned with a patterned edge of the first layer of photoresist.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not necessarily indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A photomask blank, comprising:
a substrate;
a lower hard mask region on the substrate;
an absorbing region on the lower hard mask region; and
an upper hard mask region on the absorbing region.

2. The photomask blank of claim 1, wherein the lower hard mask region and the absorbing region have a combined optical density of at least 2.8 for light with an exposure wavelength of about 193 nanometers.

3. The photomask blank of claim 2, the exposure wavelength is about 193 nanometers.

4. The photomask blank of claim 1, wherein the lower hard mask region and the absorbing region have a combined optical density of at least 3.0 for light with a wavelength of about 193 nanometers, and wherein the absorbing region alone has an optical density of less than 3.0 for light with a wavelength of about 193 nanometers.

5. The photomask blank of claim 1, wherein both the lower hard mask region and the upper hard mask region comprise chromium.

6. The photomask blank of claim 1, wherein both the lower hard mask region and the upper hard mask region consist of substantially the same material.

7. The photomask blank of claim 6, wherein the upper hard mask region has a thickness of at least 1.5 times that of the lower hard mask region.

8. The photomask blank of claim 7, wherein the absorbing region comprises MoSi and has a thickness great enough that the absorbing region and lower hard mask region have a combined optical density of at least 2.8 for light with a wavelength of about 193 nanometers.

9. The photomask blank of claim 1, wherein the lower hard mask region comprises a refractory metal and has a thickness of less than 200 angstroms.

10. The photomask blank of claim 9, wherein the lower hard mask region comprises a material selected from the group consisting of chromium oxide and chromium oxynitride.

11. The photomask blank of claim 9, wherein the substrate comprises quartz and the lower hard mask region is in direct contact with the quartz substrate.

12. The photomask blank of claim 1, wherein:
the lower hard mask region comprises a refractory metal, is in direct contact with the substrate, and has a thickness of 150 angstroms or less;
the upper hard mask region consists substantially of the same material as the lower hard mask region and has a thickness of at least twice that of the lower hard mask region.

13. The photomask blank of claim 12, wherein:
the substrate comprises quartz;
the refractory metal is chromium;
the absorbing region comprises molybdenum and silicon; and
the lower hard mask region and the absorbing region have a combined optical density of at least 2.8 for light with a wavelength of about 193 nanometers.

14. A method of patterning a photomask blank comprising a substrate, a first hard mask region on the substrate, an absorbing region on the first hard mask region, and a second hard mask region on the absorbing region, comprising:
patterning a patterning layer so that some portions of the second hard mask region are covered by the patterning layer and some portions of the second hard mask region are exposed portions;
removing exposed portions of the second hard mask region with a first process that selectively removes the second hard mask region at a rate greater than the absorbing region, to expose portions of the absorbing region under the removed portions of the second hard mask region;
removing exposed portions of the absorbing region with a second process that selectively removes the absorbing region at a rate greater than the first hard mask region, to expose portions of the first hard mask region under the removed portions of the absorbing region;
removing exposed portions of the first hard mask region with a third process that selectively removes the first hard mask region at a rate greater than the substrate, to expose portions of the substrate under the removed portions of the first hard mask region; and
removing exposed portions of the substrate to form trenches in the substrate.

15. The method of claim 14, wherein the first, second, and third processes are all plasma etches.

16. The method of claim 15, wherein the first and third processes use substantially the same plasma etch.

17. The method of claim 16, wherein the first hard mask region and the second hard mask region both consist of substantially the same material, with the second hard mask region having a thickness of at least 1.5 times a thickness of the first hard mask region prior to patterning of the photomask blank.

18. The method of claim 14, further comprising:
depositing, after removing exposed portions of the absorbing region, a second patterning layer on exposed portions of the first hard mask region and remaining portions of the second hard mask region; and
patterning the second patterning layer to expose some portions of the first hard mask region, while still covering other portions of the first hard mask region, whereby the third process removes the portions of the first hard mask region exposed by the patterning of the second patterning layer.

19. The method of claim 14, wherein the absorbing region comprises MoSi and has a thickness great enough that the absorbing region has an optical density of at least 2.8 for light with an exposure wavelength, the first, second, and third processes are wet etches, wherein the etchant used in the first and third processes comprise chlorine, the etchant used in the second process comprises flourine, and removing exposed portions of the substrate comprises etching the exposed portions of the substrate with a fourth etchant comprising flourine.

20. The method of claim 14, wherein the first hard mask region is in direct contact with the substrate.
